(19) United States
(12) Patent Application Publication
(10) Pub. No.: US 2026/0005169 A1
(43) Pub. Date: Jan. 1, 2026

(54) SEMICONDUCTOR STRUCTURE AND SEMICONDUCTOR INTEGRATED STRUCTURE

(71) Applicant: CXMT Corporation, Hefei City (CN)

(72) Inventor: Hongkai JI, Hefei City (CN)

(73) Assignee: CXMT Corporation, Hefei City (CN)

(21) Appl. No.: 19/265,478

(22) Filed: Jul. 10, 2025

Related U.S. Application Data
(63) Continuation of application No. PCT/CN2025/085550, filed on Mar. 28, 2025.

(30) Foreign Application Priority Data
Jun. 26, 2024 (CN) 202410846462.9

(51) Int. Cl. H01L 23/00; H01L 23/528; H01L 25/065

(52) U.S. Cl. CPC H01L 24/05; H01L 23/5283; H01L 24/08; H01L 25/0657; H01L 2224/05557; H01L 2224/08145

(57) ABSTRACT

Embodiments of the present disclosure provide a semiconductor structure, including: a substrate, where the substrate is covered with a dielectric layer, and the dielectric layer includes a first region and a second region that surrounds the first region; a first conductive pad disposed in the dielectric layer of the first region, where a top surface of the first conductive pad has a recessed or protruded part, and the dielectric layer covers the top surface of the first conductive pad; and a first bonding pad disposed in the dielectric layer of the second region, where the first bonding pad is disposed around the first conductive pad, the first bonding pad has a top surface exposed to the dielectric layer, and a bottom surface of the first bonding pad is higher than the top surface of the first conductive pad.

### CROSS-REFERENCE TO RELATED APPLICATIONS

This application is a continuation of International Patent Application No. PCT/CN2025/085550 filed on Mar. 28, 2025, which claims priority to Chinese Patent Application No. 202410846462.9 filed on Jun. 26, 2024. The disclosures of the above-referenced applications are hereby incorporated by reference in their entirety.

### BACKGROUND

Direct bonding (Direct Bonding) is a micro-electronic fabrication technology, and means that two semiconductor wafers or other planar materials are tightly connected by means of direct contact and interaction of inter-atomic forces in case of no intermediates. Hybrid bonding (Hybrid Bonding) is one of semiconductor integration technologies, and combines features of direct bonding and metal interconnection. In hybrid bonding, direct bonding is used in some regions to form a strong connection through interaction between atoms, while in other specific regions, an electrical connection is implemented through metal contact or metal-to-metal bonding. The direct bonding technology and the hybrid bonding technology are usually used in chip stacking, 3D integrated circuits, micro-electronic mechanical systems (MEMS), and other micro-nano systems, and have broad application prospects.

Regardless of direct bonding or hybrid bonding, there is an extremely high requirement on surface flatness of a bonded surface before bonding is performed. For example, in a hybrid bonding process, a direct bonding region requires extremely high surface cleanliness and extremely low surface roughness, so as to ensure close contact between atoms and good bonding quality. Any surface roughness, particle, or defect may result in bonding failure or a degradation in electrical performance. Therefore, in order to increase a bonding yield, surface processing of wafers is essential before hybrid bonding is performed. Various chemical mechanical polishing (CMP) technologies or other cleaning technologies are usually used to optimize surface flatness and cleanliness, but also cause additional costs.

### SUMMARY

Embodiments of the present disclosure relate to the technical field of semiconductors, and in particular, to a semiconductor structure and a semiconductor integrated structure.

Embodiments of the present disclosure provide a semiconductor structure with a higher yield and lower fabrication costs.

A problem to be solved by technical spirits of the present disclosure is not limited to the above-mentioned problem, and a person skilled in the art clearly understands other unmentioned problems from the following description.

According to an example implementation of the present disclosure, a semiconductor structure includes: a substrate, where the substrate is covered with a dielectric layer, and the dielectric layer includes a first region and a second region that surrounds the first region; a first conductive pad disposed in the dielectric layer of the first region, where a top surface of the first conductive pad has a recessed or protruded part, and the dielectric layer covers the top surface of the first conductive pad; and a first bonding pad disposed in the dielectric layer of the second region, where the first bonding pad is disposed around the first conductive pad, the first bonding pad has a top surface exposed to the dielectric layer, and a bottom surface of the first bonding pad is higher than the top surface of the first conductive pad.

According to an example implementation of the present disclosure, a semiconductor integrated structure is further provided, including a first semiconductor structure and a second semiconductor structure that are connected through opposite bonding surfaces. The first semiconductor structure includes: a substrate, where the substrate is covered with a dielectric layer, and the dielectric layer includes a first region and a second region that surrounds the first region; a first conductive pad disposed in the dielectric layer of the first region, where a top surface of the first conductive pad has a recessed or protruded part, and the dielectric layer covers the top surface of the first conductive pad; and a first bonding pad disposed in the dielectric layer of the second region, where the first bonding pad is disposed around the first conductive pad, the first bonding pad has a top surface exposed to the dielectric layer, a bottom surface of the first bonding pad is higher than the top surface of the first conductive pad, and the top surface, exposed to the dielectric layer, of the first bonding pad and a top surface of the dielectric layer serve as a bonding surface of the first semiconductor structure. The second semiconductor structure includes: a substrate, where the substrate is covered with a dielectric layer, and the dielectric layer includes a third region and a fourth region that surrounds the third region; a third conductive pad disposed in the dielectric layer of the third region, where a top surface of the third conductive pad has a recessed or protruded part, and the dielectric layer covers the top surface of the third conductive pad; and a fourth bonding pad disposed in the dielectric layer of the third region, where the fourth bonding pad is disposed around the third conductive pad, the fourth bonding pad has a top surface exposed to the dielectric layer, a bottom surface of the fourth bonding pad is higher than the top surface of the third conductive pad, and a top surface, exposed to the dielectric layer, of the fourth bonding pad and the top surface of the dielectric layer serve as a bonding surface of the second semiconductor structure. The bonding surface of the first semiconductor structure is aligned with and bonded to the bonding surface of the second semiconductor structure.

### BRIEF DESCRIPTION OF DRAWINGS

The drawings herein, which are incorporated in and constitute a part of this specification, illustrate embodiments consistent with the embodiments of the present disclosure, and serve to explain the principles of the embodiments of the present disclosure together with this specification.

FIG. 1A to FIG. 1C are schematic diagrams of a semiconductor structure according to some embodiments of the present disclosure;

FIG. 2A to FIG. 2C are schematic diagrams of a semiconductor structure according to some embodiments of the present disclosure;

FIG. 3A and FIG. 3B are schematic diagrams of a semiconductor structure according to some embodiments of the present disclosure;

FIG. 4A to FIG. 4D are schematic diagrams of a semiconductor structure according to some embodiments of the present disclosure;

FIG. 5A and FIG. 5B are schematic diagrams of a semiconductor structure according to some embodiments of the present disclosure;

FIG. 6 is a schematic diagram of a semiconductor integrated structure according to some embodiments of the present disclosure; and

FIG. 7A to FIG. 7D are sectional views formed at specific positions in steps for fabricating a semiconductor structure according to some embodiments of the present disclosure, and are used to describe a method for fabricating the semiconductor structure in embodiments conceived according to the present disclosure.

Through the drawings, clear embodiments of the present disclosure have already been shown, and are described in more detail below. These drawings and text descriptions are not intended to limit the scope of the concept of the embodiments of the present disclosure in any manner, but to describe the embodiments of the present disclosure for a person skilled in the art with reference to specific embodiments.

### DETAILED DESCRIPTION

The technical solutions in the embodiments of the present disclosure are clearly and completely described below with reference to the drawings in the embodiments of the present disclosure. It may be understood that specific embodiments described herein are merely intended to explain related disclosures, but are not intended to limit the present disclosure. In addition, it further needs to be noted that for ease of description, only related parts are shown in the drawings. Unless otherwise defined, all technical and scientific terms used in this specification have meanings the same as those commonly understood by a person skilled in the technical field of the present disclosure. The terms employed in this specification are merely intended to describe the embodiments of the present disclosure, but are not intended to limit the present disclosure. “Some embodiments” describing a subset of all possible embodiments is involved in the following descriptions. However, it may be understood that “some embodiments” may be the same subset or different subsets of all the possible embodiments, and may be combined with each other when there is no conflict. It should be noted that the term “first/second/third” in the embodiments of the present disclosure is merely intended to distinguish between similar objects, and does not represent specific sorting for the objects. It may be understood that “first/second/third” may be interchanged for a specific sequence or order if allowed, so that the embodiments of the present disclosure described herein can be implemented in a sequence other than those shown or described.

The following describes the embodiments of the present disclosure in detail with reference to the drawings.

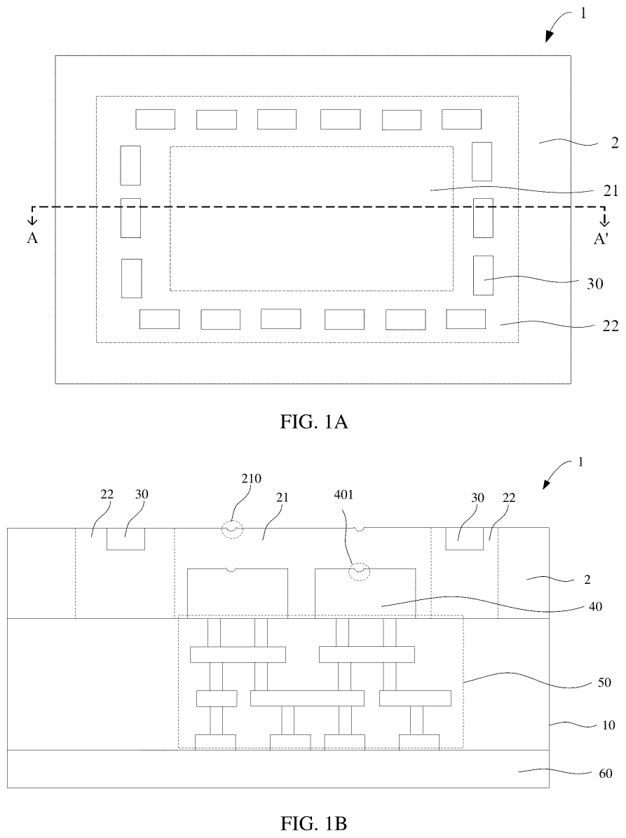

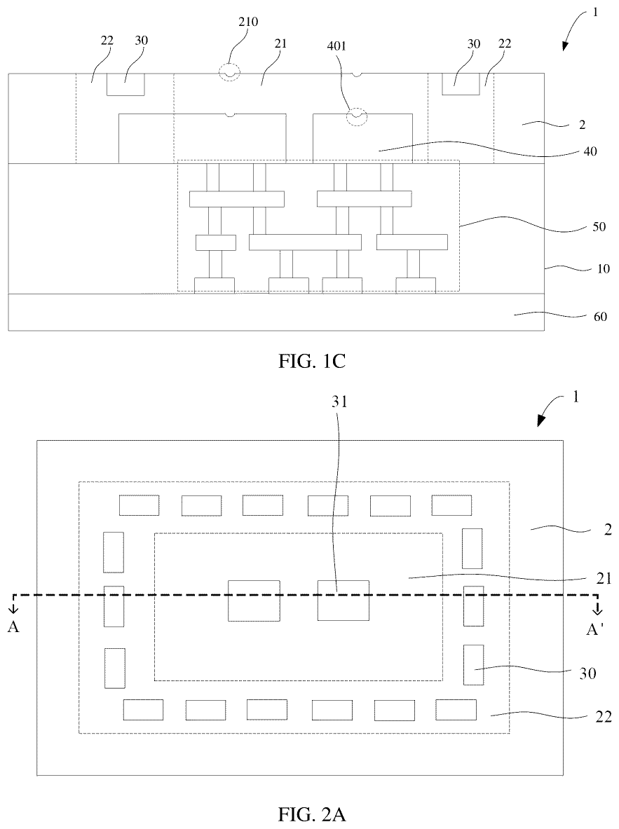

In some embodiments of the present disclosure, a semiconductor structure 1 is provided. Referring to FIG. 1A and FIG. 1B, FIG. 1A is a top plane view of a semiconductor structure 1, and FIG. 1B is a cross-sectional view along a line A-A′ in FIG. 1A. The semiconductor structure 1 includes a substrate 10 and a dielectric layer 2 that covers the substrate 10. The dielectric layer 2 includes a first region 21 and a second region 22 that are located on the substrate 10. In a top view plane, the second region 22 is a region around a periphery of the first region 21. A first conductive pad 40 is disposed in the dielectric layer 2 of the first region 21, and a top surface of the first conductive pad 40 is covered by the dielectric layer 2. A first bonding pad 30 is disposed in the dielectric layer 2 of the second region 22. A bottom surface of the first bonding pad 30 is higher than the top surface of the first conductive pad 40. A top surface of the first bonding pad 30 is exposed to a top surface of the dielectric layer 2, that is, the first bonding pad 30 is formed in the dielectric layer 2 located above the first conductive pad 40, and the top surface of the first bonding pad 30 is not covered by the dielectric layer 2. The first bonding pad 30 surrounds the first conductive pad 40, that is, a projection of a graph formed by the first bonding pad 30 on the top surface of the dielectric layer 2 surrounds a projection of the first conductive pad 40 on the top surface of the dielectric layer 2. In these embodiments, the first region 21 may be a region located at the center of the substrate 10.

In some embodiments, the first conductive pad 40 has a first part and a second part. A top surface 401 of the first part is recessed or protruded relative to a top surface of the second part. The top surface 401 may alternatively be a top surface having both a recess and a protrusion. The dielectric layer 2 conformally covers the top surface 401.

In some other embodiments, referring to FIG. 1C, the first conductive pad 40 has an extension part 402 extending into the second region 22. The first bonding pad 30 is disposed in in the dielectric layer 2 on the extension part 402. The recessed or protruded top surface 401 on the top surface of the first conductive pad 40 is located on the top surface of the first conductive pad 40 in the first region 21. In some embodiments, the extension part 402 may further extend into a second region 22 on another side of the first region 21.

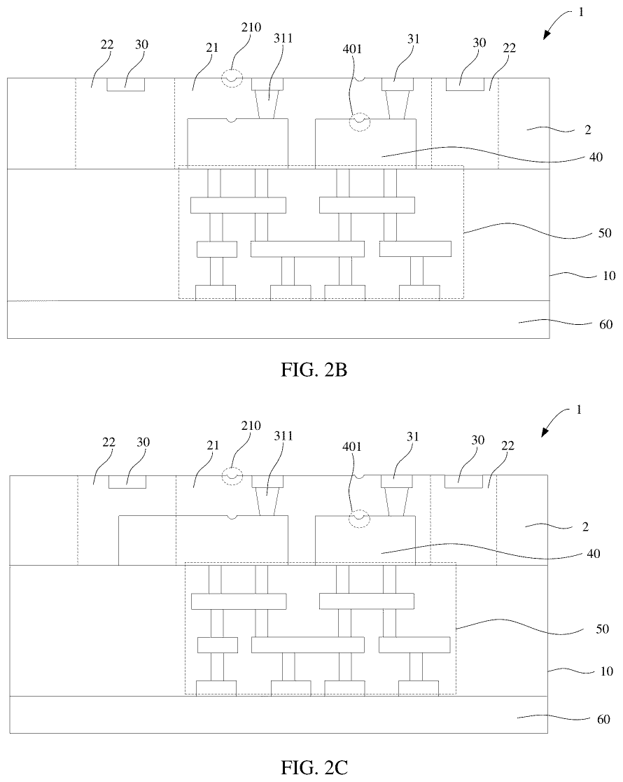

In some embodiments, a plurality of first bonding pads 30 are uniformly distributed in the second region 22, as shown in FIG. 1A and FIG. 2A. The first bonding pad 30 may be a circular bonding pad or a generally circular bonding pad, and the first bonding pad 30 may alternatively be a quadrilateral bonding pad, for example, a square or a rectangle.

In some embodiments, the first conductive pad 40 may be a metal pad formed by combining one or more of metals such as aluminum metal, copper metal, and nickel metal. The first bonding pad 30 may be copper, copper alloy, nickel, aluminum, tungsten, and a combination thereof. In some embodiments, the first conductive pad 40 and the first bonding pad 30 may include different conductive materials. For example, the first conductive pad 40 includes aluminum, and the first bonding pad 30 includes copper.

In some embodiments, the dielectric layer 2 may be a stacked structure including multiple dielectric layers. For example, the first conductive pad 40 is located in one dielectric layer, and the first bonding pad 30 is located in another dielectric layer.

In these embodiments, because the first region 21 and the second region 22 each include the dielectric layer 2, the first region 21 and the second region 22 each are a part defined in the dielectric layer 2. There is no clear boundary between the two regions, and the two regions are defined by positions of the first conductive pad 40 and the first bonding pad 30.

Because the first conductive pad 40 has an uneven top surface, there is an unexpected height difference between a surface of the dielectric layer 2 of the first region 21 that includes the first conductive pad 40 and a surface of the dielectric layer 2 of the second region 22 that does not include the first conductive pad 40. Such unexpected height difference causes a difference between the two regions in bonding performance, thereby affecting a bonding effect. In these embodiments, the first bonding pad 30 disposed around the dielectric layer 2 above the periphery of the first conductive pad 40 can effectively improve the impact on the bonding effect because of the height difference between the first region 21 and the second region 22. The presence of the first bonding pad 30 can control occurrence of a poor bonding effect to be between the first region 21 and the second region 22, so as to prevent an impact of the poor bonding effect on another region. A region in which the first bonding pad 30 is located may be set based on the size of a protruded or recessed region on the top surface of the first conductive pad 40, that is, the minimum distance between the first bonding pad 30 and the protruded or recessed region on the top surface of the first conductive pad 40 in the horizontal direction is controlled to meet a preset distance. That is, when the first conductive pad 40 has a part extending into the second region 22, the first bonding pad may alternatively be disposed on the extension part of the first conductive pad 40. In this way, the sizes of the first region 21 and the second region 22 can be controlled, so as to prevent a waste of an effective area on the substrate.

In some embodiments, the minimum distance between the first bonding pad 30 and the protruded or recessed region 401 on the top surface of the first conductive pad 40 in the horizontal direction is 0.5 microns to 5 microns, for example, may be 0.5 microns to 1 micron, 1 micron to 3 microns, 2.5 microns to 4 microns, or 4 microns to 5 microns.

In some embodiments, the width of the first conductive pad 40 on a horizontal plane is 2 microns to 5 microns. The maximum width of the protruded or recessed region 401 on the top surface of the first conductive pad 40 on a horizontal plane is 0.5 microns to 1.5 microns.

Provided in some embodiments is another semiconductor structure 1, which is different from semiconductor structures shown in FIG. 1A to FIG. 1C.

The semiconductor structure 1 in these embodiments has a second bonding pad 31 disposed on the first conductive pad 40. Specifically, referring to FIG. 2A and FIG. 2B, FIG. 2A is a top plane view of the semiconductor structure 1, and FIG. 2B is a cross-sectional view along a line A-A′ in FIG. 2A.

The second bonding pad 31 is disposed in the dielectric layer 2 of the first region 21, and is disposed above the first conductive pad 40. In some embodiments, a projection of the second bonding pad 31 on the top surface of the dielectric layer 2 is located in a projection of the first conductive pad 40 on the top surface of the dielectric layer 2. The second bonding pad 31 is connected to the first conductive pad 40 through an interconnection structure 311, and a top surface of the second bonding pad 31 is exposed to the top surface of the dielectric layer 2, that is, the top surface of the second bonding pad 31 is not covered by the dielectric layer 2. A bottom surface of the interconnection structure 311 is disposed on a top surface of the second part of the first conductive pad 40, and the bottom surface of the interconnection structure 311 is not in contact with the top surface 401 of the first part of the first conductive pad 40. In some embodiments, the bottom surface of the interconnection structure 311 may alternatively be in contact with the top surface 401.

In some embodiments, as shown in FIG. 2C, FIG. 2C is a cross-sectional view along a line A-A′ in FIG. 2A. The first conductive pad 40 includes an extension part 402 extending into the dielectric layer 2 of the second region 22, and the extension parts 402 extends into the dielectric layer 2 below the first bonding pad 30. In some embodiments, the extension part 402 may alternatively extend into the second region 22 on another side of the first region 21.

In some embodiments, a plurality of first conductive pads 40 in the first region 21 may be disposed, and a plurality of second bonding pads 31 corresponding to the first conductive pads 40 may further be disposed. The second bonding pad 31 may be a circular bonding pad or a generally circular bonding pad, and the second bonding pad 31 may alternatively be a quadrilateral bonding pad, for example, a square or a rectangle.

In some embodiments, the second bonding pad 31 is disposed in the dielectric layer 2 above the first conductive pad 40, that is, the second bonding pad 31 may not be electrically connected to the first conductive pad 40. In these embodiments, a bottom surface of the first bonding pad 30 and a bottom surface of the second bonding pad 31 are located on the same plane.

In these embodiments, the second bonding pad 31 may alternatively be disposed on the top surface of the first conductive pad 40. By disposing the second bonding pad 31, a poor bonding effect between the first region 21 and the second region 22 may be further controlled to be within a region between the top surface of the first bonding pad 30 and the top surface of the second bonding pad 31, thereby reducing a region area affected by the poor bonding effect.

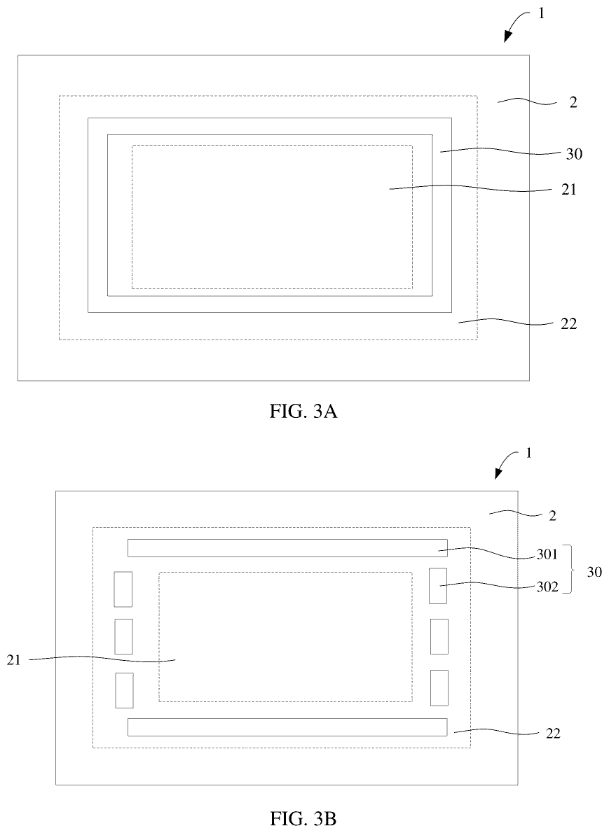

In some other embodiments, the first bonding pad 30 has an overall structure that surrounds the first region 21. As shown in FIG. 3A and FIG. 3B, FIG. 3A shows that the first bonding pad 30 includes a bonding pad 301 that extends on one side of the second region 22 and exists in an overall structure, and a plurality of bonding pads 302 that are separated from each other on the other side of the second region 22. The bonding pads 301 may be distributed on two opposite sides of the second region 22. The bonding pads 302 may be distributed on other two opposite sides of the second region 22. FIG. 3B shows a schematic diagram of the first bonding pad 30 being an overall structure around the first region 21. It should be noted that the overall structure herein means that the structure exists as a whole, and parts that are separated from each other do not exist.

In some embodiments, the bonding pads 301 may be distributed on one side or more than two sides of the second region 22. In some embodiments, the bonding pads 302 may be distributed on one side or more than two sides of the second region 22, and the bonding pad 302 may alternatively be an overall structure extending on one side of the second region 22.

In these embodiments, by using the first bonding pad 30 with an overall structure, a poor bonding effect in the first region 21 can be controlled more reliably. Meanwhile, the first bonding pad 30 with an overall structure can further improve heat dissipation and thermal conductivity of the semiconductor structure.

In some embodiments, the first conductive pad 40 is a test pad or a test bonding pad for executing a circuit probe test (CP Test), and the protruded or recessed top surface 401 of the first conductive pad 40 may be a region in which a probe mark is formed after the test probe is in contact with the top surface of the first conductive pad 40. The top surface of the first conductive pad 40 is further covered with a barrier layer (not shown in the figure). The barrier layer is formed between the dielectric layer 2 and the top surface of the first conductive pad 40. The barrier layer on the protruded or recessed top surface 401 is removed in a probe test process, so that the top surface 401 is directly in contact with the dielectric layer 2. The material of the barrier layer may be titanium nitride.

In some embodiments, the first bonding pad 30 is a virtual metal pad through which no current passes, and the second bonding pad 31 may be a virtual metal pad through which no current passes or a metal pad through which current passes. In this case, the current is conducted through the first conductive pad 40 and the second bonding pad 31. The second bonding pad 31 may be copper, copper alloy, nickel, aluminum, tungsten, and a combination thereof.

In some embodiments, the dielectric layer 2 may be a stacked structure including multiple dielectric layers. For example, the first conductive pad 40 is located in one dielectric layer, and the first bonding pad 30 and the second bonding pad 31 are located in another dielectric layer.

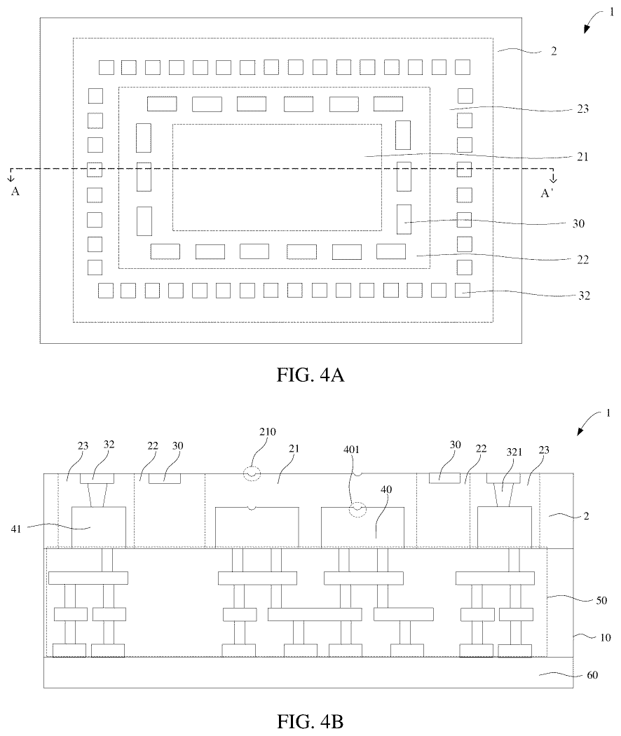

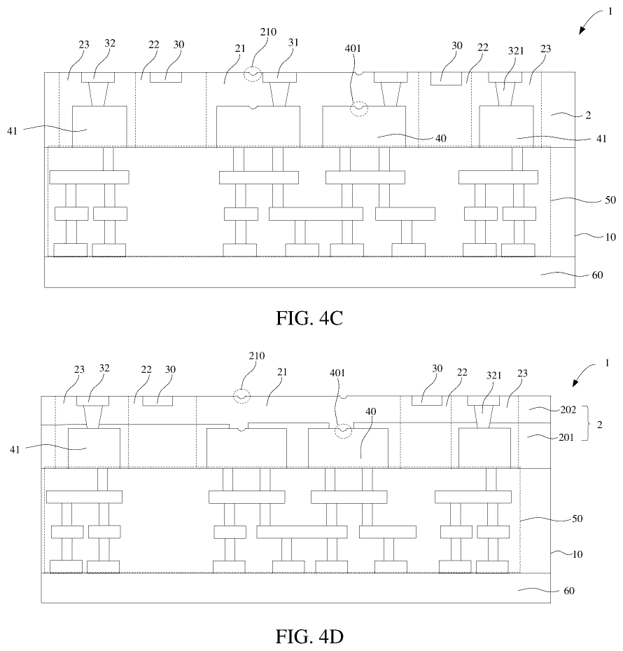

In some embodiments, provided is another semiconductor structure 1. Refer to FIG. 4A and FIG. 4B. FIG. 4a is a top plan view of the semiconductor structure 1, and FIG. 4B is a cross-sectional view along a line A-A′ in FIG. 4A. The dielectric layer 2 covering the semiconductor structure 1 further includes a third region 23 located outside the second region 22. A second conductive pad 41 is disposed in the third region 23. A third bonding pad 32 is disposed in the dielectric layer 2 above the second conductive pad 41. A bottom surface of the third bonding pad 32 is electrically connected to a top surface of the second conductive pad 41 through an interconnection structure 321 disposed therebetween. The third bonding pad 32 further has a top surface exposed to the dielectric layer 2. In these embodiments, the first region 21 may be a region located at the center of the substrate 10, and the third region 23 may be a region at an edge of the substrate 10.

In some embodiments, the third bonding pad 32 may be directly electrically connected to the second conductive pad 41. That is, the bottom surface of the third bonding pad 32 abuts against the top surface of the second conductive pad 41.

In some embodiments, a plurality of third bonding pads 32 are uniformly distributed in the third region 23. A plurality of first bonding pads 30 are uniformly distributed in the second region 22. There is a first spacing between the first bonding pads 30. There is a second spacing between the third bonding pads 32. The first spacing is greater than the second spacing. In some embodiments, the first spacing may be 0.5 microns to 2 microns, and the second spacing may be 0.2 microns to 1 micron.

In some embodiments, the first bonding pad 30 and the third bonding pad 32 may have same or approximately same shapes, for example, are both circular bonding pads, generally circular bonding pads, or quadrilateral bonding pads, for example, squares or rectangles. In some embodiments, the first bonding pad 30 and the third bonding pad 32 may alternatively have same or approximately same surface areas. Specifically, in the horizontal direction, the widths or the diameters of the first bonding pad 30 and the third bonding pad 32 may be the same. In some embodiments, the surface area of the first bonding pad 30 is greater than that of the third bonding pad 32. For example, in the horizontal direction, the width or the diameter of the first bonding pad 30 is greater than that of the third bonding pad 32. In some embodiments, the width or the diameter of the first bonding pad 30 is 0.05 microns to 2 microns, and the width or the diameter of the third bonding pad 32 is 0.05 microns to 1.5 microns.

In some embodiments, the first conductive pad 40 and the second conductive pad 41 may be formed in the same step of a metal interconnection wiring process. In this case, a bottom surface of the second conductive pad 41 and a bottom surface of the first conductive pad 40 are coplanar. A top surface of the second conductive pad 41 does not have a protruded or recessed part, that is, the top surface of the second conductive pad 41 and the top surface of the second part of the first conductive pad 40 may be coplanar or approximately coplanar. In some embodiments, the first conductive pad 40 and the second conductive pad 41 may be metal pads formed by combining one or more of metals such as aluminum metal, copper metal, and nickel metal. For example, the first conductive pad 40 and the second conductive pad 41 are both aluminum-containing metal pads.

Still referring to FIG. 4C, provided in FIG. 4C is another semiconductor structure 1. Based on the semiconductor structure in FIG. 4A, the semiconductor structure further includes a second bonding pad 31 located in the first region 21, and the second bonding pad 31 is located on the first conductive pad 40, and is connected to the first conductive pad 40. For a positional relation between the second bonding pad 31 and the first conductive pad 40, refer to description in the foregoing embodiments, and details are not described herein again. The second bonding pad 31, the first bonding pad 30, and the third bonding pad 32 may have same or approximately same shapes, for example, are all circular bonding pads, generally circular bonding pads, or quadrilateral bonding pads, such as squares or rectangles. In some embodiments, the second bonding pad 31, the first bonding pad 30, and the third bonding pad 32 may alternatively have same or approximately same surface areas. Specifically, in the horizontal direction, the widths or the diameters of the second bonding pad 31, the first bonding pad 30, and the third bonding pad 32 may be the same. In some embodiments, the surface area of the second bonding pad 31 is greater than those of the first bonding pad 30 and the third bonding pad 32. For example, in the horizontal direction, the width or the diameter of the second bonding pad 31 is greater than that of the first bonding pad 30 and the third bonding pad 32. In some embodiments, the width or the diameter of the second bonding pad 31 is 0.1 microns to 2 microns. In some embodiments, a plurality of second bonding pads 31 in the first region 21 are disposed. The plurality of second bonding pads 31 may be uniformly distributed in the first region 21, or may be non-uniformly distributed in the first region 21. A spacing between each second bonding pad 31 and each first bonding pad 30 may be equal to or greater than that between each first bonding pad 30 and each third bonding pad 32.

In some embodiments, the second conductive pad 41 is a signal pad or a signal bonding pad that is different from the first conductive pad 40.

In some embodiments, the top surface of the dielectric layer 2 of the first region 21 has a protruded or recessed part surface 210 relative to the top surface of the dielectric layer 2 of the second region 22, as shown in FIG. 1A to FIG. 4C. A projection of the top surface 401 of the first conductive pad 40 on the top surface of the dielectric layer 2 of the first region 21 overlaps the surface 210.

In some embodiments, as shown in FIG. 4D, the dielectric layer 2 includes a first dielectric layer 201 and a second dielectric layer 202. The second dielectric layer 202 is formed on the first dielectric layer 201. The first conductive pad 40 and the second conductive pad 41 are formed on the first dielectric layer 201. The first bonding pad 30 is formed in the second dielectric layer 202, that is, the first conductive pad 40, the second conductive pad 41, and the first bonding pad 30 are formed in different dielectric layers. In some embodiments, the third bonding pad 32 is also formed in the second dielectric layer 202. The interconnection structure 321 passes through the first dielectric layer 201 and the second dielectric layer 202 to be connected to the second conductive pad 41. The top surface of the first conductive pad 40 has a part that is not covered by the first dielectric layer 201. For example, the top surface 401 is not covered by the first dielectric layer 201, and the second dielectric layer 202 covers a top surface that is of the first conductive pad 40 and that is not covered by the first dielectric layer 201. For example, the second dielectric layer 202 covers the top surface 401.

In some embodiments, the first dielectric layer 201 and the second dielectric layer 202 may be single-layer dielectric layers that include a single dielectric layer or multi-layer dielectric layers that include multiple dielectric layers. For example, the first dielectric layer 201 may be a stacked structure that includes one or two of silicon oxide and silicon nitride, and the second dielectric layer 202 may be a stacked structure that includes one or more of silicon oxide, silicon carbon nitride, silicon nitride, and silicon carbon oxide.

In some embodiments, there is further a barrier layer between the first conductive pad 40 and the first dielectric layer 201, and between the second conductive pad 41 and the first dielectric layer 201. The barrier layer may be a material layer of titanium nitride, tungsten nitride, or the like to prevent diffusion or anti-etch reflection of the first conductive pad 40 and the second conductive pad 41.

The semiconductor structure in the embodiments of the present disclosure includes a device layer 60 located in the substrate 10 and an interconnection layer 50 located in the device layer 60. The device layer 60 is electrically connected to the first conductive pad 40 and the second conductive pad 41 through the interconnection layer 50. The device layer 60 may include a storage unit and/or a control unit. For example, the device layer 60 includes a DRAM storage unit and/or a control unit including a CMOS transistor. The interconnection layer 50 may include multiple layers of metal conductors and an interconnection structure that connects the multiple layers of metal conductors. In some embodiments, the interconnection layer 50 may alternatively be formed by using only one layer of metal conductor, for example, may be a conductive through hole structure.

In some embodiments, the top surfaces, exposed to the dielectric layer 2, of the first bonding pad 30, the second bonding pad 31, and the third bonding pad 32 and the top surface of the dielectric layer 2 are surfaces that are of the semiconductor structure and that are used to implement bonding with another semiconductor structure.

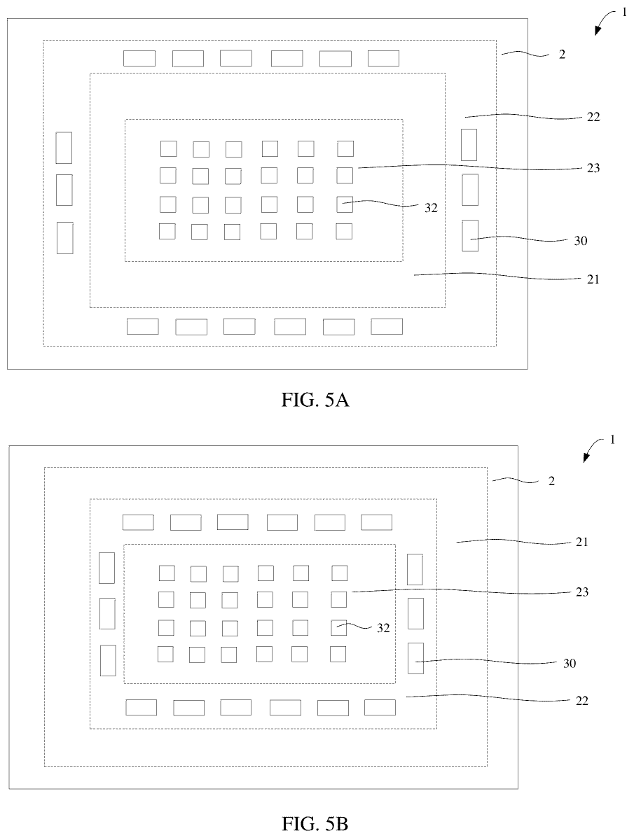

In some other embodiments, the third region 23 may alternatively be disposed in the first region 21, as shown in FIG. 5A. The first region 21 is disposed around the third region 23. The third bonding pad 32 is disposed in the third region in the first region 21. In these embodiments, the third region 23 may be a region located at the center of the substrate 10, and the first region 21 and the second region 22 may be regions located at an edge of the substrate 10. For arrangement of the first bonding pad 30, the third bonding pad 32, the conductive pad in the dielectric layer, and the like, refer to the foregoing embodiments, and details are not described herein again.

In some other embodiments, as shown in FIG. 5B, the third region 23 is surrounded by the second region 22. In this case, the first region 21 is located in the outermost layer of the dielectric layer 2, the second region 22 surrounds an outer edge of the first region 21, and the third region 23 is disposed in the second region 22. In these embodiments, the third region 23 may be a region located at the center of the substrate 10, and the first region 21 and the second region 22 may be regions located at an edge of the substrate 10. For arrangement of the first bonding pad 30, the third bonding pad 32, the conductive pad in the dielectric layer, and the like, refer to the foregoing embodiment, and details are not described herein again.

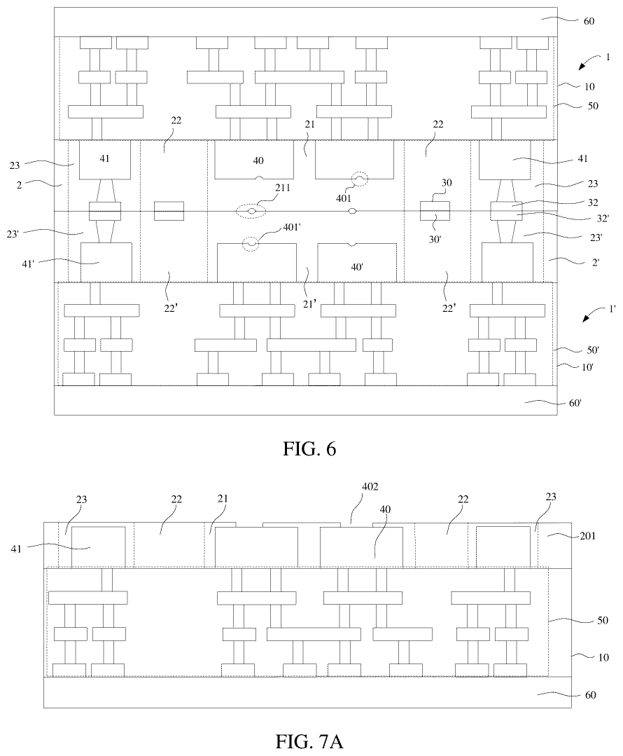

Embodiments of the present disclosure further provide a semiconductor integrated structure, including a first semiconductor structure 1 and a second semiconductor structure 1′ that are connected through opposite bonding surfaces. As shown in FIG. 6, the first semiconductor structure 1 includes a substrate 10 and a dielectric layer 2 that covers the substrate 10. The dielectric layer 2 has a first region 21 and a second region 22 that surrounds the first region 21. A first conductive pad 40 is separately disposed in the dielectric layer 2 of the first region 21. A first bonding pad 30 is disposed in the dielectric layer 2 of the second region 22. The first bonding pad 30 is not connected to the first conductive pad 40. A top surface of the first conductive pad 40 has a recessed or protruded top surface 401, and the first conductive pad 40 is electrically connected to a device layer 60 through an interconnection structure 50. The semiconductor structure 1′ includes a substrate 10′ and a dielectric layer 2′ that covers the substrate 10′. The dielectric layer 2′ has a third region 21′ and a fourth region 22′ that respectively correspond to the first region 21 and the second region 22 of the first semiconductor structure 1. Similar to the first semiconductor structure 1, a third conductive pad 40′ is disposed in the dielectric layer 2′ of the third region 21′ of the second semiconductor structure 1′, a third bonding pad 30′ is disposed in the dielectric layer 2 of the fourth region 22′, and the third bonding pad 30′ is not electrically connected to the third conductive pad 40′. A top surface of the third conductive pad 40′ has a recessed or protruded top surface 401′, and the third conductive pad 40′ is electrically connected to a device layer 60′ through an interconnection structure 50′.

In some embodiments, surfaces of the dielectric layer 2 and the first bonding pad 30 of the first semiconductor structure 1 are used as bonding surfaces, and surfaces of the dielectric layer 2′ and the third bonding pad 30′ of the second semiconductor structure 1′ are used as bonding surfaces. The bonding surfaces are mutually bonded and connected, where the first bonding pad 30 is aligned with and connected to the third bonding pad 30′.

In some embodiments, the first bonding pad 30 and the third bonding pad 30′ in the first semiconductor structure 1 and the second semiconductor structure 1′ are designed in mirror symmetry along the bonding surfaces.

In some embodiments, the first semiconductor structure 1 and the second semiconductor structure 1′ further have corresponding regions 23 and 23′ respectively. A bonding pad 32 is further disposed in the region 23. The bonding pad 32 is electrically connected to the conductive pad 41 disposed in the region 23. The conductive pad 41 is further connected to the device layer 60 through a part of the interconnection structure 50. A bonding pad 32′ corresponding to the bonding pad 32 and a conductive pad 41′ located below the bonding pad 32′ and electrically connected to the bonding pad 32′ are disposed in the region 23′ of the second semiconductor structure 1′, and the conductive pad 41′ is connected to the device layer 60′ through a part of the interconnection structure 50′. The bonding pad 32 and the bonding pad 32′ are aligned and bonded.

In some embodiments, surfaces on which the first semiconductor structure 1 and the second semiconductor structure 1′ are bonded have a bonding void 211, and the bonding void 211 is disposed between the first region 21 and the third region 21′. In some embodiments, one or more bonding void 211 may be disposed.

In some embodiments, the first semiconductor structure 1 and the second semiconductor structure 1′ may be the same type of semiconductor structures, for example, both are DRAM structures. The first semiconductor structure 1 and the second semiconductor structure 1′ may alternatively be different types of semiconductor structures. For example, one is a semiconductor structure that includes a storage unit, and the other is a semiconductor structure that includes a logic unit.

In the semiconductor structure of the embodiments of the present disclosure, a void that is left on a first conductive pad and a bonding void caused by a protrusion are controlled to be within the first region, and the first bonding pad in the second region can effectively prevent the bonding void from extending from the first region to another region. This is because in a bonding process, an expansion amount of the first bonding pad may be greater than that of the dielectric layer. Therefore, when the dielectric layer of the first region is bonded, the first bonding pad may also be firmly connected, and bonding strength of the first bonding pad is greater than that between dielectric layers. Therefore, an extension path of the bonding void in the first region is controlled by the first bonding pad, so that the bonding void can neither extend into the third region nor have a negative impact on bonding of the third bonding pad.

To make content of the present disclosure clearer, the following provides further description of a process of forming a semiconductor structure.

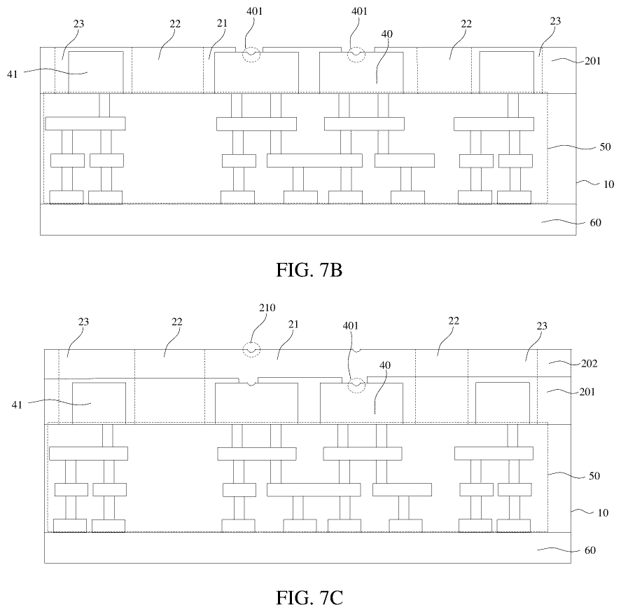

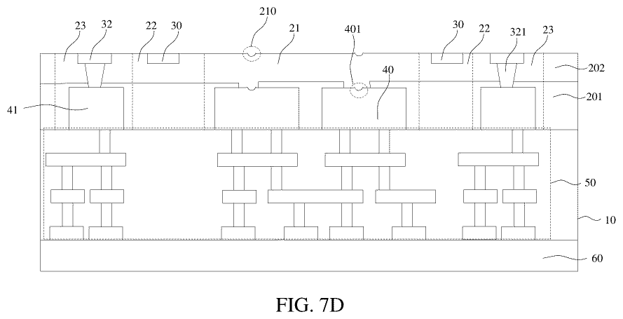

Refer to FIG. 7A to FIG. 7D. FIG. 7A to FIG. 7D are cross-sectional views of a semiconductor device according to embodiments of the present disclosure in a forming sequence.

In some embodiments, as shown in FIG. 7A, provided is a substrate 10. A device layer 60 is disposed in the substrate 10. A semiconductor device, such as a transistor, is disposed in the device layer 60. An interconnection layer 50 is disposed on the device layer 60. A first dielectric layer 201 is disposed on the interconnection layer 50. A first conductive pad 40 and a second conductive pad 41 that are electrically connected to the interconnection layer 50 are disposed on the first dielectric layer 201. A gap 402 is disposed in the first dielectric layer 201, and a part surface of the first conductive pad 40 is exposed by the gap 402. In some embodiments, a part surface of the second conductive pad 41 may alternatively be exposed. In some embodiments, the substrate 10 is a wafer.

Still referring to FIG. 7B, after a part surface of the first conductive pad 40 is exposed, a CP test is applied to the first conductive pad 40. A test process is performed by pressing a probe of a tester onto a surface exposed by the first conductive pad 40. Because the first conductive pad 40 is softer relative to the probe, after the test is completed, the surface exposed by the first conductive pad 40 is damaged by the probe, so as to form a recessed or protruded part surface 401 relative to another surface, not damaged by the probe, of the first conductive pad 40.

Still referring to FIG. 7C, after the test is completed, a second dielectric layer 202 is formed on the first dielectric layer 201. The second dielectric layer 202 covers the part surface 401 of the first conductive pad. The surface of the second dielectric layer 202 has a protruded or recessed uneven part 210.

Due to the presence of the part surface 401 of the first conductive pad 40, the surface of the second dielectric layer 202 formed by using a thin film deposition process such as CVD may further form an uneven region 210. Generally, an uneven surface of the second dielectric layer 202 is unexpected, because this will cause a risk of failure of a process step after the second dielectric layer 202 is formed. In order to obtain the second dielectric layer 202 with a relatively flat surface, multiple planarization processes are required, which means that a thicker second dielectric layer needs to be deposited when a planarization process is performed. However, the thicker second dielectric layer, on the contrary, may further amplify a height difference between the uneven region 210 in another region, thereby increasing load of the planarization process. Different from the prior art, in the embodiments of the present disclosure, a planarization process, such as a CMP process, is not required after the second dielectric layer 202 is formed, so that a relatively thinner second dielectric layer 202 can be formed.

Still referring to FIG. 7D, after the second dielectric layer 202 is formed, the first bonding pad 30 located in the second region 22, the interconnection structure 321, and the third bonding pad 32 located in the third region 23 are formed in the second dielectric layer 202. A process of forming the first bonding pad 30 and the third bonding pad 32 is a damascene process or a process of forming a metal interconnection structure that is known to a person skilled in the art. In a process of forming the first bonding pad 30 and the third bonding pad 32, deposition and planarization processes of a metal thin film are involved. A planarization process of the process mainly lies in that surfaces of the first bonding pad 30 and the third bonding pad 32 are relatively flat surfaces. Therefore, after the first bonding pad 30 and the third bonding pad 32 are formed, there is still an uneven region 210 on the surface of the second dielectric layer 202.

In some embodiments, a bonding pad 31 connected to the first conductive pad 40 may further be synchronously formed in the first region 21. For a final structure, refer to FIG. 4C.

In some embodiments, the second dielectric layer 202 may be a structure of multiple dielectric layers, such as a stacked structure of silicon oxide and silicon carbon nitride. The first bonding pad 30 and the third bonding pad 32 have a part formed in the silicon oxide and a part formed in the silicon carbon nitride.

After the first bonding pad 30 and the third bonding pad 32 are formed, a surface of the semiconductor structure may be processed to form a bonding surface, so as to perform bonding connection with another semiconductor structure. For a structure after a plurality of semiconductor structures are bonded, refer to FIG. 6. A bonding process is a direct bonding process or a hybrid bonding process. In the bonding process, the first bonding pad 30 and the third bonding pad 32 are bonded to each other, and dielectric layers of regions are bonded to each other, and uneven surfaces 210 are not bonded to each other, so as to form a bonding void 211 on the bonding surface.

In a process of forming a semiconductor structure in the embodiments of the present disclosure, a high-precision dielectric layer planarization process does not need to be used, which helps reduce process costs.

A person of ordinary skill in the art may understand that the foregoing implementations are specific embodiments for implementing the present disclosure. In an actual application, various modifications may be made to the forms and details of the implementations without departing from the spirit and scope of the embodiments of the present disclosure. Any person skilled in the art may make changes and modifications without departing from the spirit and scope of the embodiments of the present disclosure. Therefore, the protection scope of the embodiments of the present disclosure shall be subject to the scope defined by the claims.

What is claimed is:

1. A semiconductor structure, comprising:
a substrate, wherein the substrate is covered with a dielectric layer, and the dielectric layer comprises a first region and a second region that surrounds the first region;
a first conductive pad disposed in the dielectric layer of the first region, wherein a top surface of the first conductive pad has a recessed or protruded part, and the dielectric layer covers the top surface of the first conductive pad; and
a first bonding pad disposed in the dielectric layer of the second region, wherein the first bonding pad is disposed around the first conductive pad, the first bonding pad has a top surface exposed to the dielectric layer, and a bottom surface of the first bonding pad is higher than the top surface of the first conductive pad.

2. The semiconductor structure according to claim 1, further comprising a second bonding pad disposed in the dielectric layer of the first region, wherein a bottom surface of the second bonding pad is electrically connected to the top surface of the first conductive pad, and the second bonding pad has a top surface exposed to the dielectric layer.

3. The semiconductor structure according to claim 1, wherein the first conductive pad further comprises an extension part, the extension part extends into the dielectric layer of the second region, and the first bonding pad is disposed in the dielectric layer on the extension part.

4. The semiconductor structure according to claim 3, further comprising a second bonding pad disposed in the dielectric layer of the first region, a bottom surface of the second bonding pad is electrically connected to the top surface of the first conductive pad, and the second bonding pad has a top surface exposed to the dielectric layer.

5. The semiconductor structure according to claim 1, wherein the substrate further comprises a third region, the third region is disposed outside the second region or inside the second region, the dielectric layer covers the third region, a second conductive pad and a third bonding pad are disposed in the dielectric layer of the third region, a bottom surface of the third bonding pad is electrically connected to a top surface of the second conductive pad, a bottom surface of the second conductive pad and a bottom surface of the first conductive pad are coplanar, and the third bonding pad has a top surface exposed to the dielectric layer.

6. The semiconductor structure according to claim 1, wherein a surface of the dielectric layer of the first region has a protruded or recessed part relative to a surface of the dielectric layer of the second region.

7. The semiconductor structure according to claim 5, wherein the second region comprises a plurality of uniformly distributed first bonding pads, the third region comprises a plurality of uniformly distributed third bonding pads, and a spacing between the first bonding pads is greater than that between the third bonding pads.

8. The semiconductor structure according to claim 5, wherein in a first direction, the second region comprises at least one integrally connected first bonding pad, and the third region comprises a plurality of spaced third bonding pads.

9. The semiconductor structure according to claim 2, wherein the first conductive pad comprises a first part and a second part, the protruded or recessed part on the top surface of the first conductive pad is located in the first part, and the second bonding pad is formed on the second part and connected to the second part.

10. The semiconductor structure according to claim 1, wherein the first conductive pad is a test pad.

11. The semiconductor structure according to claim 5, wherein the second conductive pad is a signal pad.

12. A semiconductor integrated structure, comprising a first semiconductor structure and a second semiconductor structure that are connected through opposite bonding surfaces, wherein the first semiconductor structure comprises:
a substrate, wherein the substrate is covered with a dielectric layer, and the dielectric layer comprises a first region and a second region that surrounds the first region;
a first conductive pad disposed in the dielectric layer of the first region, wherein a top surface of the first conductive pad has a recessed or protruded part, and the dielectric layer covers the top surface of the first conductive pad; and
a first bonding pad disposed in the dielectric layer of the second region, wherein the first bonding pad is disposed around the first conductive pad, the first bonding pad has a top surface exposed to the dielectric layer, a bottom surface of the first bonding pad is higher than the top surface of the first conductive pad, and the top surface, exposed to the dielectric layer, of the first bonding pad and a top surface of the dielectric layer serve as a bonding surface of the first semiconductor structure;
the second semiconductor structure comprises:
a substrate, wherein the substrate is covered with a dielectric layer, and the dielectric layer comprises a third region and a fourth region that surrounds the third region;
a third conductive pad disposed in the dielectric layer of the third region, wherein a top surface of the third conductive pad has a recessed or protruded part, and the dielectric layer covers the top surface of the third conductive pad; and
a fourth bonding pad disposed in the dielectric layer of the third region, wherein the fourth bonding pad is disposed around the third conductive pad, the fourth bonding pad has a top surface exposed to the dielectric layer, a bottom surface of the fourth bonding pad is higher than the top surface of the third conductive pad, and the top surface, exposed to the dielectric layer, of the fourth bonding pad and the top surface of the dielectric layer serve as a bonding surface of the second semiconductor structure; and
the bonding surface of the first semiconductor structure is aligned with and bonded to the bonding surface of the second semiconductor structure.

13. The integrated structure according to claim 12, further comprising a bonding void located between the bonding surfaces, wherein the bonding void is located between the top surface of the dielectric layer of the first region and the top surface of the dielectric layer of the third region.
